(19) United States
(12) Patent Application Publication
(10) Pub. No.: US 2025/0151584 A1
(43) Pub. Date: May 8, 2025

(54) DISPLAY MODULE

(71) Applicants: TCL CHINA STAR OPTOELECTRONICS TECHNOLOGY CO., LTD., Shenzhen (CN); South China University of Technology, Guangzhou (CN)

(72) Inventors: Jiangbo YAO, Shenzhen (CN); Junbiao PENG, Shenzhen (CN); Changming XIANG, Shenzhen (CN); Rui ZHAO, Shenzhen (CN); Weiji ZHANG, Shenzhen (CN)

(73) Assignees: TCL CHINA STAR OPTOELECTRONICS TECHNOLOGY CO., LTD., Shenzhen (CN); South China University of Technology, Guangzhou (CN)

(21) Appl. No.: 18/513,678

(22) Filed: Nov. 20, 2023

(30) Foreign Application Priority Data
Nov. 6, 2023 (CN) 202311464144.8

(51) Int. Cl. H10K 59/80; H01L 25/16; H01L 33/50; H01L 33/58; H10K 59/38

(52) U.S. Cl. CPC H10K 59/879; H01L 25/167; H10H 20/8512; H10H 20/855; H10K 59/38

(57) ABSTRACT

The present application provides a display module including a first display substrate and a second display substrate. The first display substrate includes a first substrate and a plurality of first light-emitting units. The plurality of first light-emitting units are disposed at intervals on the first substrate. The second display substrate is disposed on a backside of a light-emitting side of the first display substrate, and includes a second substrate and a plurality of second light-emitting units. The plurality of second light-emitting units are disposed at intervals on the second substrate, and are staggeredly disposed with the plurality of first light-emitting units, respectively. The display module has a high resolution.

### CROSS-REFERENCE TO RELATED APPLICATION

This application claims priority to Chinese Patent Application Serial No. 202311464144.8 filed to China National Intellectual Property Administration on Nov. 6, 2023, which are incorporated by reference in the present application with its entirety.

### TECHNICAL FIELD

The present application relates to the field of display technologies, and especially relates to a display module.

### BACKGROUND

Three-dimensional (3D) display is a new display technology that has wide application prospects. For example, three-dimensional (3D) display can be applied into vehicle displays, indoor cinemas, and outdoor advertisings. 3D display modes that are commonly used include a grating mode and a lenticular lens mode. Due to simple structure of the grating mode, the grating mode is the most commonly used 3D display mode. However, slit designs of the grating mode sacrifice pixel densities.

Currently, how to improve the pixel densities of 3D display devices of the grating mode is a technical problem that needs to be solved.

### SUMMARY

An object of the present application is to provide a display module, which is beneficial to improving a resolution of the display module.

The present application provides a display module, including:
a first display substrate including a first substrate and a plurality of first light-emitting units, the plurality of first light-emitting units are disposed at intervals on the first substrate; and
a second display substrate disposed on a backside of a light-emitting side of the first display substrate and including a second substrate and a plurality of second light-emitting units; the plurality of second light-emitting units are disposed at intervals on the second substrate, and are staggeredly disposed with the plurality of first light-emitting units, respectively.

Beneficial effects of some embodiments of the present application include that the second display substrate is disposed on the backside of the light-emitting side of the first display substrate. The first display substrate includes the plurality of first light-emitting units, and the second display substrate includes the plurality of second light-emitting units. The plurality of second light-emitting units are staggeredly disposed with the plurality of first light-emitting units, respectively. With this design, the number of light-emitting units of the display module is equal to a sum of the number of the first light-emitting units and the number of the second light-emitting units, which is beneficial to improving the resolution of the display module.

### BRIEF DESCRIPTION OF THE DRAWINGS

FIG. 1 is a schematic cross-sectional structural diagram of a display module according to some embodiments of the present application.

FIG. 2 is a schematic cross-sectional structural diagram of a display module according to some other embodiments of the present application.

FIG. 3 is a schematic cross-sectional structural diagram of a display module according to further embodiments of the present application.

FIG. 4 is a schematic cross-sectional structural diagram of a light scattering unit according to some embodiments of the present application.

FIG. 5 is a schematic cross-sectional structural diagram of a display module according to some other embodiments of the present application.

FIG. 6 is a schematic cross-sectional structural diagram of a display module according to some other embodiments of the present application.

FIG. 7 is a schematic cross-sectional structural diagram of a color conversion unit in some other embodiments of the present application.

FIG. 8 is a schematic cross-sectional structural diagram of a color conversion unit in further embodiments of the present application.

FIG. 9 is a schematic diagram of a planar layout of a light-shielding layer, first light-emitting units, and second light-emitting units in some embodiments of the present application.

FIG. 10 is a schematic cross-sectional structural diagram of a display module according to further embodiments of the present application.

Elements in the accompanying drawings are designed by reference numerals listed below.

100, display module; 11, first display substrate; 111, first substrate; 112, first light-emitting unit; 113, first driving circuit; 12, second display substrate; 121, second substrate; 122, second light-emitting unit; 123, second driving circuit; 13, adhesive member; 14, dimming module; 141, light condensing unit; 141a, convex curving surface; 142, light scattering unit; 1421, light-transmitting base material; 1422, scattering particle; 142a, concave curving surface; 143, color conversion unit; 1431, color conversion base material; 1432, color conversion particle; 15, encapsulation layer; 151, transparent encapsulation adhesive layer; 152, encapsulation cover; 16, light-shielding layer; 161, first opening; 162, second opening; 17, optical modulation layer; 181, third substrate.

### DETAILED DESCRIPTION OF THE EMBODIMENT

The technical solutions in the embodiments of the present application are clearly and completely described below in conjunction with the drawings in the embodiments of the present application. Obviously, the embodiments described are only a part of the embodiments of the present application, rather than all the embodiments. Based on the embodiments in the present application, all other embodiments obtained by those skilled in the art without creative works should be deemed as falling within the claims of the present application.

Please refer to FIGS. 1 to 10, a display module 100 applied to three-dimensional (3D) display is provided by the present application. A pixel density of the display module 100 is increased, that is, a resolution of the display module 100 is increased, so as to improve a display effect in a case that the display module 100 is applied to 3D display. A technical solution of the present application is illustrated below.

Please refer to FIG. 1, which is a schematic cross-sectional structural diagram of a display module according to some embodiments of the present application. The display module 100 includes a first display substrate 11, a second display substrate 12, and an adhesive member 13. The second display substrate 12 is disposed on a backside of a light-emitting side of the first display substrate 11. The adhesive member 13 is disposed between the first display substrate 11 and the second display substrate 12, and adheres the first display substrate 11 and the second display substrate 12. The adhesive member 13 includes a frame adhesive.

Both the first display substrate 11 and the second display substrate 12 can emit lights, and both are configured to display. In a direction that the first display substrate 11 points to the second display substrate 12, an outer contour of the first display substrate 11 and an outer contour of the second display substrate 12 are level or substantially level with each other. That is, dimensions of the first display substrate 11 and the second display substrate 12 are substantially the same. It can be understood that the dimension of the second display substrate 12 may also be larger than the dimension of the first display substrate 11.

In some embodiments, both the number of the first display substrate 11 and the number of the second display substrate 12 are one. In some other embodiments, the number of first display substrate 11 and the number of second display substrate 12 may also be more than one. A plurality of the first display substrates 11 are spliced to each other, and a plurality of the second display substrates 12 are spliced to each other. In the present application, a technical solution of the present application is described in detail with a case that both the number of the first display substrate 11 and the number of the second display substrate 12 are one.

In some embodiments, the first display substrate 11 includes a first substrate 111 and a plurality of first light-emitting units 112. The plurality of first light-emitting units 112 are disposed at intervals on the first substrate 111. The second display substrate 12 includes a second substrate 121 and a plurality of second light-emitting units 122. The plurality of second light-emitting units 122 are disposed at intervals on the second substrate 121, and are staggeredly disposed with the plurality of first light-emitting units, respectively. In the direction that the first display substrate 11 points to the second display substrate 12, the first display substrate 11 overlaps with the second display substrate 12.

In some embodiments of the present application, the second display substrate 12 is disposed on the backside of the light-emitting side of the first display substrate 11. The first display substrate 11 includes the plurality of first light-emitting units 112, and the second display substrate 12 includes the plurality of second light-emitting units 122. The plurality of second light-emitting units 122 are staggeredly disposed with the plurality of first light-emitting units 112, respectively. With this design, the number of light-emitting units of the display module 100 is equal to a sum of the number of the first light-emitting units 112 and the number of the second light-emitting units 122. The plurality of the first light-emitting units 112 and the plurality of second light-emitting units 122 display as independent pixels, so that the display module 100 has a high resolution. Furthermore, the first display substrate 11 may only be provided with the first light-emitting units 112 and driving circuits corresponding to the first light-emitting units 112, and the second display substrate 12 may only be provided with only the second light-emitting units 122 and driving circuits corresponding to the second light-emitting units 122. Manufacturing processes of the first display substrate 11 and the second display substrate 12 are simpler, thereby simplifying manufacturing processes of the display module 100.

It should be noted that in some related technologies, in a case that a plurality of light-emitting units and driving circuits of the plurality of the light-emitting units are fabricated on one substrate, a circuit design of corresponding driving circuits becomes more complex as the number of the light-emitting units increases. As a result, process of display devices is relatively more difficult. However, in some embodiments of the present application, with a design that the first display substrate 11 and the second display substrate 12 are stacked, and the plurality of first light-emitting units 112 are staggeredly disposed with the plurality of second light-emitting units 122. As a result, the display module 100 achieves the high resolution while manufacturing processes of the display module 100 are simplified.

In some embodiments, orthographic projections of the plurality of first light-emitting units 112 on the second substrate 121 are adjacent to and spaced apart from orthographic projections of the plurality of second light-emitting units 122 on the second substrate 121, respectively. As such, in a case that the plurality of first light-emitting units 112 are staggeredly disposed with the plurality of second light-emitting units 122, each second light-emitting unit 122 overlaps with a region between adjacent two first light-emitting units 112, respectively. There is more space for disposing the second light-emitting units 122. The number of the second light-emitting units 122 can be greater, thereby further improving the resolution of the display module 100.

It should be noted that in the present application, an orthographic projection is a projection in a direction that the first display substrate 11 points to the second display substrate 12.

In some embodiments, orthographic projection of at least one first light-emitting unit 112 on the second substrate 121 is disposed between orthographic projections of adjacent two second light-emitting units 122 on the second substrate 121. For example, an orthographic projection of the first light-emitting unit 112 on the second substrate 121 is disposed between the orthographic projections of the adjacent two second light-emitting units 122 on the second substrate 121. Or, orthographic projections of two or more first light-emitting unit 112 on the second substrate 121 are disposed between the orthographic projections of the adjacent two second light-emitting units 122 on the second substrate 121.

In some embodiments, the display module 100 may also include a third display substrate (not shown). The third display substrate is disposed on a side of the second display substrate 12 away from the first display substrate 11, but is not limited thereto. The second display substrate 12 is disposed on a light-emitting side of the third display substrate. Third light-emitting units provided in the third display substrate are staggeredly disposed with the first light-emitting units and the second light-emitting units.

In some embodiments, at least one first light-emitting unit 112 is the same as at least one second light-emitting unit 122. In this case, a color of a light emitted by the at least one first light-emitting unit 112 is the same as a color of a light emitted by the at least one second light-emitting unit 122. With this design, the at least one first light-emitting unit 112 and the at least one second light-emitting unit 122, which are same, can be disposed on the first substrate 111 and the second substrate 121, respectively. For example, the at least one first light-emitting unit 112 and the at least one second light-emitting unit 122 both emit a first color light. The first color light includes a white light. The first color light may also include any one of green light, blue light, red light, and yellow light.

It should be noted that in a case that both the first light-emitting unit 112 and the second light-emitting unit 122 emit the white lights, both the first light-emitting unit 112 and the second light-emitting unit 122 include a red light-emitting device, a blue light-emitting device and a green light-emitting device. That is, both the first light-emitting unit 112 and the second light-emitting unit 122 include hybrid light-emitting devices.

In some embodiments, a light emitted by at least one first light-emitting unit 112 is different from a light emitted by at least one second light-emitting unit 122. With this design, the at least one first light-emitting unit 112 and the at least one second light-emitting unit 122, which emit lights of different colors, can be disposed on the first substrate 111 and the second substrate 121, respectively. For example, the at least one first light-emitting unit 112 emits one of red light, blue light, and green light, and the at least one second light-emitting unit 122 emits another one of red light, blue light, and green light.

In some embodiments, colors of lights emitted by the plurality of first light-emitting units 112 are the same. For example, the plurality of first light-emitting units 112 all emit white light. Colors of lights emitted by the plurality of second light-emitting units 122 are also the same. For example, the plurality of second light-emitting units 122 also emit white light.

In some embodiments, colors of lights emitted by the plurality of first light-emitting units 112 may also be different from each other. For example, the plurality of first light-emitting units 112 may emit red light, blue light, and green light, respectively. Colors of lights emitted by the plurality of second light-emitting units 122 may be different from each other. For example, the plurality of second light-emitting units 122 may emit red light, blue light, and green light, respectively.

In some embodiments, the first light-emitting unit 112 may include an inorganic light-emitting diode, a micro light-emitting diode (Micro-LED), and a mini light-emitting diode (Mini-LED), but is not limited thereto. The second light-emitting unit 122 may also include an inorganic light-emitting diode, a micro light-emitting diodes, and a mini light-emitting diode, but is not limited thereto. The dimension of the inorganic light-emitting diode, the dimension of the mini light-emitting diode, and the dimension of the micro light-emitting diode are successively reduced. In some other embodiments, the first light-emitting unit 112 and the second light-emitting unit 122 may also be organic light-emitting diodes or quantum light-emitting diodes, and etc.

On a basis that the display module 100 in some embodiments of the present application has high resolution, the display module 100 further includes a dimming module 14 to further improve the display effect of the display module 100. At least a portion of the dimming module 14 is disposed on a light-emitting side of the second light-emitting units 122. An orthographic projection of the dimming module 14 on the second substrate 121 overlaps with orthographic projections of the second light-emitting units 122 on the second substrate 121. The dimming module 14 is staggeredly disposed with the first light-emitting units 112. With this design, the dimming module 14 adjusts lights emitted by the second light-emitting units 122. Adjustments includes adjustments of emission angles and colors of lights emitted by the second light-emitting units 122.

It should be noted that the second light-emitting units 122 of the second display substrate 12 is farther from a light-emitting surface of the display module 100, and the first light-emitting units 112 of the first display substrate 11 is closer to the light-emitting surface of the display module 100. In order to improve display differences caused by this distance differences, the dimming module 14 is added by the present application to adjust lights emitted by the second light-emitting units 122 in the second display substrate 12.

It should also be noted that the orthographic projection of the dimming module 14 on the second substrate 121 overlaps with the orthographic projections of the second light-emitting units 122 on the second substrate 121 means that the orthographic projection of the dimming module 14 on the second substrate 121 overlaps with the orthographic projections of the second light-emitting unit 122 on the second substrate 121 in the direction that the first display substrate 11 points to the second display substrate 12.

The dimming module 14 includes a light condensing unit 141. An orthographic projection of the light condensing unit 141 on the second substrate 121 overlaps with orthographic projections of the second light-emitting unit 122 on the second substrate 121. At least a portion of the light condensing unit 141 is disposed between the second light-emitting units 122 and the first substrate 111. With this design, after lights emitted by the second light-emitting unit 122 are incident into the light condensing units 141, the light condensing units 141 converge the lights emitted by the second light-emitting unit 122, and then the lights are emitted in a form of condensing lights. Emission angles of the condensing lights are relatively less. The condensing lights pass through the first display substrate 11, and then are emitted into the external environment. Moreover, since at least a portion of the light condensing unit 141 is disposed between the second light-emitting units 122 and the first substrate 111, the lights emitted by the second light-emitting unit 122 are adjusted to be the condensing lights by the light condensing unit 141 before the lights are incident onto the first display substrate 11. As a result, possibilities of crosstalk between the condensing lights and the lights emitted by the first light-emitting units 112 of the first display substrate 11 are reduced, thereby improving display effects of the display module 100.

In some embodiments, as shown in FIG. 1, the light condensing units 141 are disposed on the second substrate 121, and a portion of the second light-emitting units 122 is embedded in the light condensing units 141. With this design, no matter the second light-emitting units 122 emit lights from side surfaces or from a front surface, or the second light-emitting unit 122 emit lights from the side surfaces and the front surface, the light condensing unit 141 has a better convergence effect on the lights emitted by the second light-emitting unit 122. Light extraction rate of the lights emitted by the second light-emitting unit 122 on a light-emitting side of the display module 100 is improved. Moreover, a portion of the second light-emitting units 122 is embedded in the light condensing units 141, so that there is no need to align the second light-emitting unit 122 and the light-condensing unit 141 with each other, thus simplifying the manufacturing processes of the display module 100.

Specifically, the second light-emitting unit 122 has a bottom surface, a top surface and side surfaces. The side surfaces are connected between the top surface and the bottom surface. The bottom surface and the top surface are arranged oppositely. The bottom surface of the second light-emitting unit 122 is fixed on the second substrate 121. The side and top surfaces of the second light-emitting unit 122 are disposed in the light condensing unit 141.

In some embodiments, in a case that the light condensing units 141 are disposed on the second substrate 121 and a portion of the second light-emitting units 122 is embedded in the light condensing units 141, the light condensing units 141 may also be in contact with the first substrate 111. As such, the display module 100 is thinner.

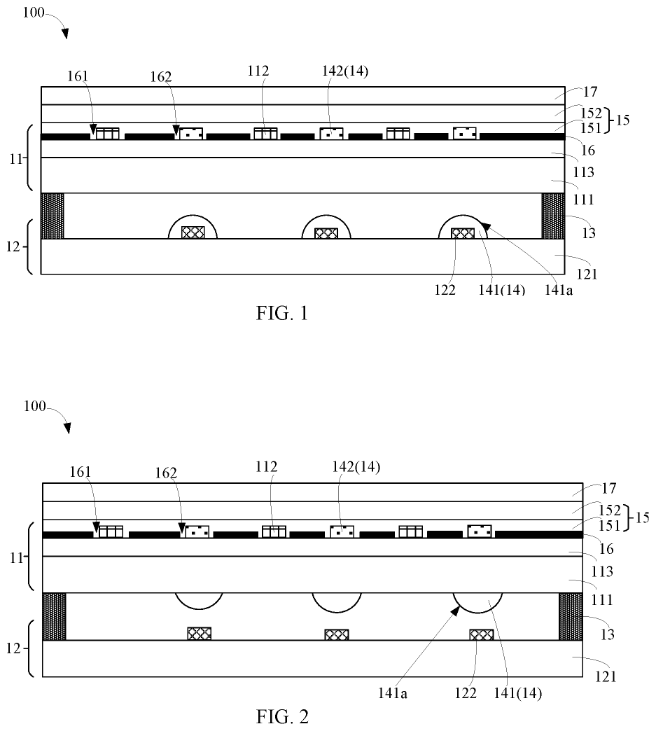

In some other embodiments, as shown in FIG. 2, the light condensing unit 141 is disposed on a surface of the first substrate 111 adjacent to the second display substrate 12. With this design, there are more spaces for arranging the second light-emitting units 122 on the second substrate 121, and there are more spaces for arranging the light condensing units 141 on the surface of the first substrate 111 adjacent to the second display substrate 12. Thus, the manufacturing processes of the display module 100 are simpler.

In some other embodiments, in a case that the light condensing unit 141 is disposed on the surface of the first substrate 111 adjacent to the second display substrate 12, there is a gap between the light condensing unit 141 and the second light-emitting units 122. With this design, a problem of causing damage to the light condensing unit 141 is improved due to a direct contact between the light condensing unit 141 and the second light-emitting unit 122. In some other embodiments, an orthographic projection of the second light-emitting unit 122 on the first substrate 111 is disposed within an orthographic projection of the light condensing unit 141 on the first substrate 111, so that more lights emitted by the second light-emitting units 122 are incident towards the light condensing unit 141, thereby improving light extraction efficiencies of the second light-emitting unit 122.

In some other embodiments, in the case that the light condensing unit 141 is disposed on the surface of the first substrate 111 adjacent to the second display substrate 12, the light condensing unit 141 may be in contact with the second light-emitting unit 122 to reduce the thickness of the display module 100.

In further embodiments, for a plurality of light condensing units 141, a part of the light condensing units 141 may be disposed on the second substrate 121, and the second light-emitting units 122 are embedded in a part of the light condensing units 141, respectively; another part of the light condensing units 141 may be disposed on the surface of the first substrate 111 adjacent to the second display substrate 12.

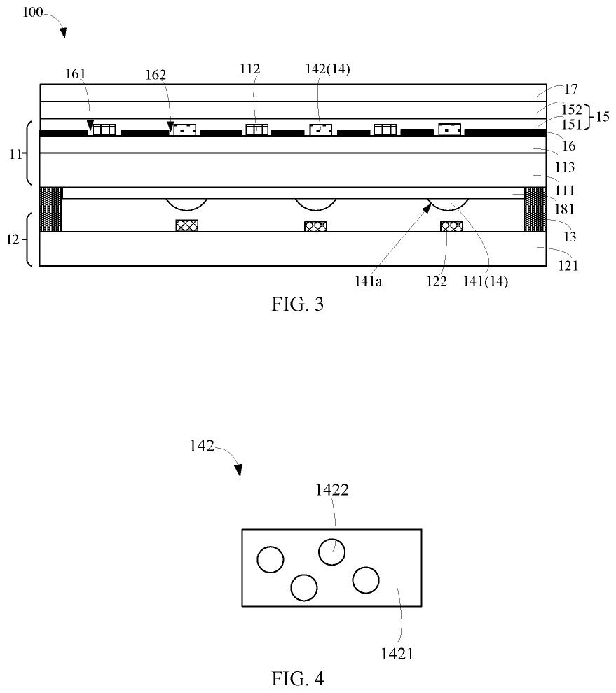

In further embodiments, as shown in FIG. 3, a plurality of light condensing units 141 may also be disposed on a third substrate 181 that is different from the first substrate 111 and the second substrate 121. The third substrate 181 is fixed to the surface of the first substrate 111 adjacent to the second substrate 121. With this design, manufacturing processes of the plurality of light condensing units 141 can be simplified. Furthermore, damages caused to the first light-emitting units 112 and the light condensing units 141 in a case that the first light-emitting unit 112 and the light-condensing unit 141 are disposed on both surfaces of the first substrate 111, respectively, can also be improved. The third substrate 181 is a transparent substrate.

Referring to FIGS. 1 to 3, the light condensing units 141 includes a condenser lens, but is not limited thereto. The condenser lens includes but is not limited to a micro convex lens, and the condenser lens includes a convex curving surface 141a. Referring to FIG. 1, in the case that a portion of the second light-emitting units 122 is embedded in the light condensing unit 141, the convex curving surface 141a protrudes toward a direction adjacent to the first display substrate 11. Referring to FIGS. 2 and 3, in a case that the light condensing unit 141 is disposed on the light-emitting side of the second light-emitting unit 122, the convex curving surface 141a of the light condensing unit 141 protrudes toward a direction adjacent to the second light-emitting units 122.

In some embodiments, a height of the light condensing unit 141 is greater than or equal to 8 microns and less than or equal to 50 microns, so as to reduce manufacturing difficulty of the light condensing units 141, and ensure light condensing effects of the light condensing unit 141. Optionally, the height of the light condensing unit 141 is greater than or equal to 12 microns and less than or equal to 28 microns. Optionally, the height of the light condensing unit 141 is greater than or equal to 15 microns and less than or equal to 25 microns.

In some embodiments, the condensing lens is transparent to ensure that the light condensing unit 141 has light transmittance. The material of the light condensing unit 141 includes but is not limited to a light-transmitting organic materials. The light-transmitting organic material include at least one of epoxy resin, polymethyl methacrylate (PMMA), and polycarbonate (PC).

Referring to FIGS. 1 to 3, the dimming module 14 further includes a light scattering unit 142. The light scattering unit 142 is disposed on a side of the light condensing unit 141 away from the second light-emitting unit 122. An orthographic projection of the light scattering unit 142 on the second substrate 121 overlaps with the orthographic projection of the light condensing unit 141 on the second substrate 121.

Specifically, the light scattering unit 142 is disposed on the first substrate 111, and is disposed adjacent to at least one first light-emitting unit 112.

A matching design of the light condensing unit 141 and the light scattering unit 142 is adopted, so that the condensing lights emitted from the light condensing unit 141 are incident into the light scattering unit 142. The condensing lights are scattered by the light scattering units 142, and then are emitted in a form of scattering lights. Emission angles of the scattering lights are greater than incident angles of the condensing lights. In other words, after the lights emitted by the second light-emitting units 122 is processed by the light condensing unit 141 and the light scattering unit 142 of the dimming module 14 in sequence, emission angles of the lights emitted by the second light-emitting units 122 are first decreased, and then are increased. Therefore, emission angles of the lights adjusted by the dimming modules 14 and the emission angles of the light emitted by the second light-emitting unit 122 tend to be the same. That is, the emission angles of the scattering lights emitted from the light scattering unit 142 are the same as the emission angles of the lights emitted by the second light-emitting unit 122. In a case that the light scattering units 142 are disposed on the first substrate 111, and the emission angles of the scattering lights emitted from the light scattering unit 142 and the emission angles of the lights emitted by the second light-emitting unit 122 tend to be the same, it is equivalent to transferring the lights emitted by the second light-emitting units 122 to the first substrate 111. That is to say, it is equivalent to arranging the second light-emitting units 122 on the first substrate 111. Pixel densities of the first display substrate 11 are increased, but there is no need to add pixel circuits of the second light-emitting unit 122 on the first display substrate 11, thereby simplifying manufacturing processes of the first display substrate 11.

In some embodiments, in the direction that the first display substrate 11 points to the second display substrate 12, the second light-emitting units 122 and the light condensing units 141 may overlap with each other in a one-to-one manner, but are not limited thereto. With this design, condensing effects of the light condensing unit 141 on the lights emitted by the second light-emitting unit 122 are ensured. In some embodiments, in the direction that the first display substrate 11 points to the second display substrate 12, the light condensing unit 141 and the light scattering unit 142 may also overlap with each other in a one-to-one manner, but is not limited thereto. With this design, scattering effects of the light scattering unit 142 on the condensing lights are ensured.

In some embodiments, referring to FIGS. 1 to 3, in a case that the first light-emitting unit 112 may include the inorganic light-emitting diode, the micro light-emitting diode, and the mini light-emitting diode, the shape of the light scattering unit 142 is the same as the shape of the first light-emitting units, and the dimension of the light scattering unit 142 is the same as the dimension of the first light-emitting units 112. With this design, a light-emitting surface of the light scattering unit 142 is the same as or tends to be the same as light-emitting surfaces of the first light-emitting units 112. The emission angles of the scattering lights emitted from the light scattering unit 142 and the emission angles of the lights emitted by the first light-emitting units 112 tend to be the same, thereby further improving the display effects of the display module 100. It can be understood that in a case that the first light-emitting unit 112 includes other types of light-emitting devices, the shape of the light scattering unit 142 may also be the same as the shape of the first light-emitting units 112, and the dimension of the light scattering unit 142 may also be the same as the dimension of the first light-emitting units 112.

Specifically, in the case that the first light-emitting unit 112 may include the inorganic light-emitting diode, the micro light-emitting diode, and the mini light-emitting diode, both the light-emitting surface of the first light-emitting unit 112 and the light-emitting surface of the light scattering unit 142 include a planar surface. The light-emitting surface of the first light-emitting unit 112 and the light-emitting surface of the light scattering unit 142 are level with each other (level with each other in a direction perpendicular to the direction that the first display substrate 11 points to the second display substrate 12) and have a same area. Therefore, there is no step difference between the light-emitting surface of the first light-emitting unit 112 and the light-emitting surface of the light scattering unit 142. That the emission angles of the lights emitted by the first light-emitting unit 112 and the emission angles of the scattering lights emitted from the light scattering unit 142 tend to be the same are ensured, thereby further improving display effects of the display module 100.

In some other embodiments, both the light-emitting surface of the first light-emitting unit 112 and the light-emitting surface of the light scattering unit 142 include a curving surface. The light-emitting surface of the first light-emitting unit 112 and the light-emitting surface of the light scattering unit 142 are the same. The emission angles of the lights emitted by the first light-emitting unit 112 and the emission angles of the scattering lights emitted from the light scattering unit 142 tend to be the same, thereby further improving the display effects of the display module 100.

In some embodiments, referring to FIG. 4, the light scattering unit 142 includes a light-transmitting base material 1421 and scattering particles 1422 dispersed in the light-transmitting base material 1421. A refractive index of the light scattering unit 142 is greater than 1 and less than or equal to 2. That more condensing lights are incident into the light scattering units 142 are ensured, and more scattering lights are emitted from the light scattering unit 142, thereby improving transmittance of the light scattering unit 142 for the condensing lights. The material of the light-transmitting base material 1421 includes a light-transmitting organic material. The light-transmitting organic material includes at least one of epoxy resin, polymethyl methacrylate, and polycarbonate. A particle size of the scattering particles 1422 is greater than or equal to 1 micron and less than or equal to 5 microns to ensure light scattering effects of the light scattering unit 142. The material of the scattering particles 1422 includes metal materials. Reflectivity of the metal materials are used in conjunction with the scattering properties of the scattering particles to ensure the scattering effects of the scattering particles 1422 on the condensing lights. The metal materials include but are not limited to aluminum, silver, copper, and alloys thereof.

In some other embodiments, as shown in FIG. 5, the light scattering unit 142 includes a scattering lens. The light scattering unit 142 includes a concave curving surface 142a. The scattering lens include a concave lens. The scattering lens is light-transmissive, and is made of a same material as the condenser lens.

In some other embodiments of the present application, in a case that the light condensing unit 141 includes a condenser lens, the light scattering unit 142 includes a scattering lens. The condenser lens combines with the scattering lens, which are more conducive to it that the emission angles of the lights emitted by the second light-emitting units 122 are decreased and increased in sequence, and then are the same as the emission angles of the lights emitted by the second light-emitting unit 122.

It should be noted that the shapes and the dimensions of the scattering lens and the condenser lens can be controlled to match each other, so as to ensure that the lights emitted by the second light-emitting unit 122 remain basically unchanged before and after being processed by the scattering lens and the condenser lens in sequence. For example, the shape of the concave curving surface 142a is the same as the shape of the convex curving surface 141a, and a curvature of the concave curving surface 142a is the same as a curvature of the convex curving surface 141a, but it is not limited thereto.

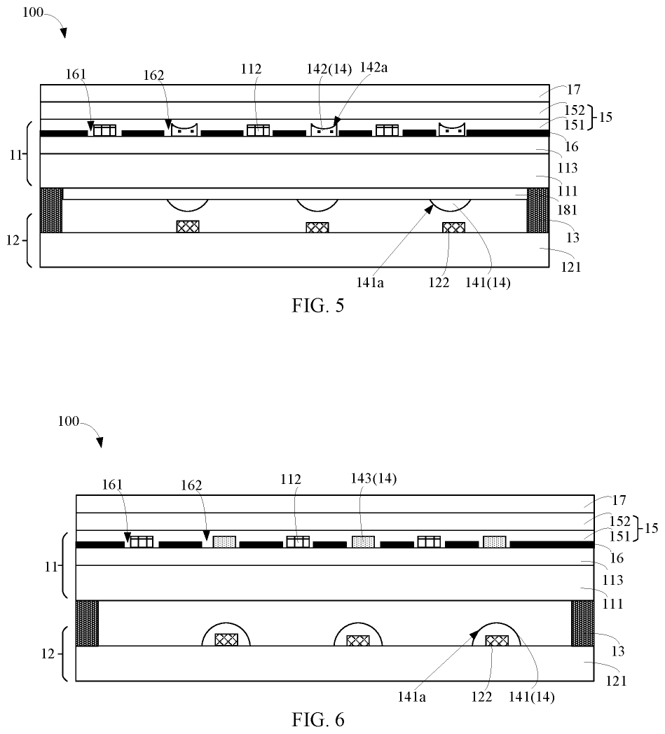

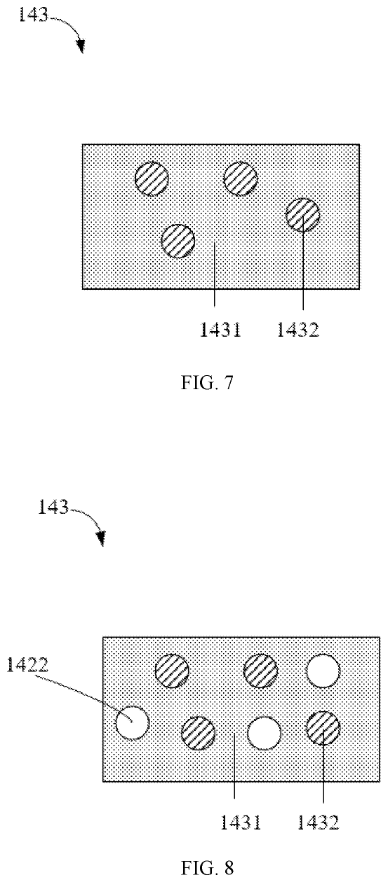

In some other embodiments, as shown in FIGS. 6 and 7, the dimming module 14 may further include a color conversion unit 143. The color conversion unit 143 is disposed on a side of the light condensing unit 141 away from the second light-emitting unit 122. An orthographic projection of the color conversion unit 143 on the second substrate 121 overlaps with the orthographic projection of the light condensing unit 141 on the second substrate 121.

Specifically, the color conversion unit 143 is disposed on the first substrate 111, and is disposed adjacent to at least one first light-emitting unit 112. The orthographic projection of the color conversion unit 143 on the second substrate 121 overlaps with the orthographic projection of the light condensing unit 141 on the second substrate 121.

In some embodiments of the present application, a matching design of the light condensing unit 141 and the color conversion unit 143 is adopted. The condensing lights emitted from the light condensing unit 141 are incident into the color conversion unit 143, and the color conversion unit 143 converts a color of the condensing lights. As a result, a color of the condensing lights before entering into the color conversion unit 143 is different from a color of the condensing lights exiting from the color conversion unit 143.

The color conversion unit 143 may include a color conversion base material 1431 and color conversion particles 1432 dispersed in the color conversion base material 1431. The color conversion particles 1432 include at least one of a quantum dot and a phosphor. The quantum dot may include at least one of a red light quantum dot, a green light quantum dot, and etc. The phosphor may include at least one of red phosphors and green phosphors.

In some embodiments, a plurality of color conversion units 143 may be the same. That is, the plurality of color conversion units 143 convert the lights emitted by the second light-emitting unit 122 into lights of a same color. For example, the second light-emitting unit 122 emits blue light, and the plurality of color conversion units 143 convert blue light into red light or green light.

In some other embodiments, the plurality of color conversion units 143 may also be different. That is, the plurality of color conversion units 143 convert the lights emitted by the second light-emitting unit 122 into lights of different colors. For example, the second light-emitting unit 122 emits blue light, and the plurality of color conversion units 143 include a first color conversion unit (not shown) and a second color conversion unit (not shown). The first color conversion unit converts blue light into red light, and the second color conversion unit converts blue light into green light.

In some other embodiments, in the case that the first light-emitting unit 112 may include the inorganic light-emitting diode, the micro light-emitting diode, and the mini light-emitting diode, the shape of the color conversion units 143 is the same as the shape of the first light-emitting units 112, and the dimension of the color conversion units 143 is the same as the dimension of the first light-emitting units 112. With this design, a light-emitting surface of the color conversion units 143 is the same as or tends to be the same as light-emitting surfaces of the first light-emitting units 112. Emission angles of color conversion lights emitted from the color conversion units 143 and the emission angles of the lights emitted by the first light-emitting units 112 tend to be the same, thereby further improving display effects of the display module 100.

In further embodiments, referring to FIG. 8, the color conversion unit 143 may also include the scattering particles 1422 in addition to the color conversion particles 1432. With this design, in addition to converting the condensing lights collected by the light condensing unit 141 into lights of different colors, the color conversion unit 143 can also scatter the lights. Furthermore, in a case that the color conversion unit 143 includes both the scattering particles 1422 and the color conversion particles 1432, scattering effects of the scattering particles 1422 on the condensing lights can improve conversion efficiencies of the color conversion particles 1432 on the condensing lights.

In further embodiments, the light scattering unit 142 and the color conversion unit 143 may also be stacked on the first substrate 111. For example, the light scattering unit 142 is disposed between the color conversion unit 143 and the first substrate 111, or, the color conversion unit 143 is disposed between the light scattering unit 142 and the first substrate 111.

In some embodiments, as shown in FIGS. 1 to 3, FIG. 5, and FIG. 6, the display module 100 may further include a light-shielding layer 16. The light-shielding layer 16 is disposed on the first substrate 111, and includes first openings 161 and second openings 162 arranged at intervals. The first light-emitting units 112 are disposed in the first openings 161. The orthographic projections of the second light-emitting units 122 on the second substrate 121 overlap with orthographic projections of the second opening 162 on the second substrate 121. The light-shielding layer 16 can improve a crosstalk problem between the lights emitted by the plurality of first light-emitting units 112 and the lights emitted by the plurality of second light-emitting units 122.

Referring to FIGS. 1 to 3, and FIG. 5, in a case that the light scattering units 142 are disposed on the first substrate 111, the light scattering units 142 are disposed in the second openings 162. Referring to FIG. 6, in a case that the color conversion units 143 are disposed on the first substrate 111, the color conversion unit 143 are disposed in the second openings 162.

In some embodiments, the thickness of the light-shielding layer 16 is less than the heights of the first light-emitting units 112 and the second light-emitting units 122. The thickness of the light shielding layer 16 is greater than or equal to 1 micron and less than or equal to 3 microns.

In some embodiments, as shown in FIGS. 1 to 3, FIG. 5, FIG. 6, and FIG. 9, there is a gap between a sidewall of the first opening 161 and the first light-emitting unit 112. That the light-shielding layer 16 has a light-shielding property is ensured, and it is more convenient for the first light-emitting units 112 to be dispose in the first openings 161, thereby simplifying the manufacturing processes of the display module 100. In the case that the color conversion units 143 and/or the light scattering units 142 are disposed in the second openings 162, there are also gaps between sidewalls of the second opening 162 and the color conversion unit 143 and/or the light scattering unit 142. Thus, it is convenient to dispose the color conversion unit 143 and/or the light scattering unit 142 into the second openings 162, thereby simplifying the manufacturing processes of the display module 100.

In some embodiments, there is also a gap between a sidewall of the second opening 162 and a corresponding one of the second light-emitting units 122. Correspondingly, orthographic projections of the second light-emitting units 122 on the second substrate 121 are disposed within the orthographic projections of the second openings 162 on the second substrate 121. As such, it is convenient for an opening area of the second opening 162 to be greater than an area of the corresponding one of the second light-emitting units 122 in a case that the corresponding one of the second light-emitting units 122 overlaps with the second opening 162, thereby simplifying the manufacturing processes of the display module 100.

In some embodiments, the opening area of the second opening 162 may be greater than an opening area of the first opening 161, so as to reduce difficulty of overlapping the second opening 162 with the second light-emitting unit 122. In some other embodiments, the opening area of the first opening 161 and the opening area of the second opening 162 may be the same, so as to reduce manufacturing difficulty of the light-shielding layer 16.

In some embodiments, the light-shielding layer 16 includes a black insulating layer. The black insulating layer includes a black matrix layer. In some other embodiments, the light-shielding layer 16 may also include a light-shielding metal layer.

In some embodiments, please continue to refer to FIGS. 1 to 3, FIG. 5, and FIG. 6, the first substrate 111 includes a glass substrate, and the second substrate 121 includes a printed circuit board. The first display substrate 11 further includes first driving circuits 113 disposed on the first substrate 111. The first driving circuits 113 are connected to the first light-emitting units 112, and the first driving circuits 113 controls the plurality of first light-emitting units 112 to display. The second substrate 121 is not provided with driving circuits of the second light-emitting units 122. The display module 100 further includes an external control circuit (not shown). The external control circuit is connected to the plurality of second light-emitting units 122, so as to control the plurality of second light-emitting units 122 to display.

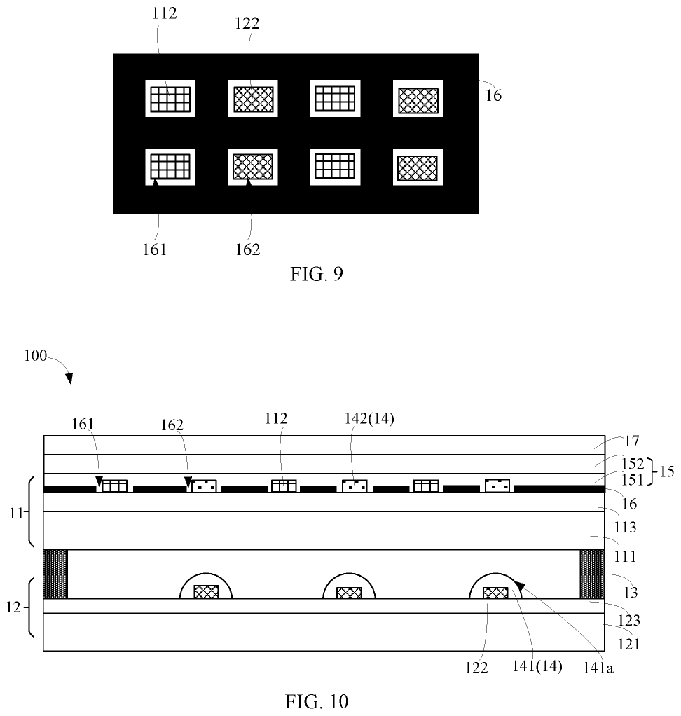

Referring to FIG. 10, both the first substrate 111 and the second substrate 121 include a glass substrate. The first display substrate 11 further includes first driving circuits 113 disposed on the first substrate 111. The first driving circuits 113 are connected to the first light-emitting units 112, and the first driving circuit 113 controls the plurality of first light-emitting units 112 to display. The second display substrate 12 further includes second driving circuits 123 disposed on the second substrate 121. The second driving circuits 123 are connected to the second light-emitting units 122, and the second driving circuits 123 drive the plurality of second light-emitting units 122 to emit lights. The first driving circuits 113 and the second driving circuits 123 may be the same.

In further embodiments, the first display substrate 11 may not include the first driving circuits 113, and the second display substrate 12 may include the second driving circuits 123.

Referring to FIGS. 1 to 3, FIG. 5, FIG. 6, and FIG. 10, the display module 100 further includes an optical modulation layer 17. The optical modulation layer 17 is disposed on the light-emitting side of the first display substrate 11. In some embodiments, the optical modulation layer 17 includes a slit grating film. In some other embodiments, the optical modulation layer 17 includes lenticular lenses.

It should be noted that in a case that the optical modulation layer 17 includes the slit grating film, shielding effects of the slit grating film is used to guide lights emitted by light-emitting units in different regions of the first display substrate 11 and the second display substrate 12 to corresponding visual fields of user's eyes, thereby generating a stereoscopic vision. In a case that the optical modulation layer 17 includes the lenticular lenses, refraction effects of the lights emitted from the first display substrate 11 by cylindrical surface of each lenticular lens are used to guide two different planar images to the corresponding visual fields of the user's eyes, thereby generating the stereoscopic vision.

It should also be noted that high-resolution design of the display module 100 of the present application can meet requirements of the slit grating film for high-resolutions, thereby improving display problems caused by a large amount of light loss caused by slit gratings.

Referring to FIGS. 1 to 3, FIG. 5, FIG. 6, and FIG. 10, the display module 100 further includes an encapsulation layer 15. The encapsulation layer 15 is disposed between the optical modulation layer 17 and the first display substrate 11. The optical modulation layer 17 is disposed on the encapsulation layer 15. The encapsulation layer 15 plays a role in encapsulating and protecting the first display substrate 11.

The encapsulation layer 15 includes a transparent encapsulation adhesive layer 151 and an encapsulation cover 152. The transparent encapsulation adhesive layer 151 is disposed between the encapsulation cover 152 and the first display substrate 11, and adheres the encapsulation cover 152 and the first display substrate 11. The transparent encapsulation adhesive layer 151 not only plays a role in encapsulating the first display substrate 11, but also plays a role in adhesion. The transparent encapsulation adhesive layer 151 includes a transparent optical adhesive. The encapsulation cover 152 includes a transparent protective cover. The encapsulation cover 152 not only encapsulates and protects the first display substrate 11, but also supports the optical modulation layer 17.

In some embodiments, the height of the adhesive member 13 is greater than or equal to 8 microns and less than or equal to 40 microns. As such, the height of the adhesive member 13 is adapted to the height of the light condensing unit 141, and the thickness of the display module 100 is reduced. Optionally, the height of the adhesive member 13 is greater than or equal to 12 microns and less than or equal to 28 microns. Optionally, the height of the adhesive member 13 is greater than or equal to 15 microns and less than or equal to 25 microns. Optionally, the height of the adhesive member 13 is greater than or equal to 18 microns and less than or equal to 22 microns.

It should be noted that the height of the adhesive member 13 of the present application is designed based on the height of the light condensing unit 141 and the thickness of the display module 100. The height of the light condensing unit 141 is related to preparation processes of the light condensing unit 141 and light condensing effects thereof.

The descriptions of the above-mentioned embodiments are only used to help understand the technical solutions and core ideas of the present application. Those of ordinary skill in the art should understand that they can still modify the technical solutions described in the foregoing embodiments, or equivalently replace some of the technical features; and these modifications or replacements do not cause the essence of the corresponding technical solutions to deviate from the scope of the technical solutions of the embodiments of the present application.

What is claimed is:

1. A display module, comprising:
a first display substrate comprising a first substrate and a plurality of first light-emitting units, wherein the plurality of first light-emitting units are disposed at intervals on the first substrate; and
a second display substrate disposed on a backside of a light-emitting side of the first display substrate and comprising a second substrate and a plurality of second light-emitting units, wherein the plurality of second light-emitting units are disposed at intervals on the second substrate, and are staggeredly disposed with the plurality of first light-emitting units, respectively.

2. The display module of claim 1, further comprising:
a dimming module, wherein at least a portion of the dimming module is disposed on a light-emitting side of the second light-emitting units, an orthographic projection of the dimming module on the second substrate overlaps with orthographic projections of the second light-emitting units on the second substrate, and the dimming module is staggeredly disposed with the first light-emitting units.

3. The display module of claim 2, wherein the dimming module comprises a light condensing unit and a light scattering unit; and
wherein at least a portion of the light condensing unit is disposed between the second light-emitting units and the first substrate, and an orthographic projection of the light condensing unit on the second substrate overlaps with the orthographic projections of the second light-emitting units on the second substrate; and
the light scattering unit is disposed on a side of the light condensing unit away from the second light-emitting units, and an orthographic projection of the light scattering unit on the second substrate overlaps with the orthographic projection of the light condensing unit on the second substrate.

4. The display module of claim 3, wherein at least one light condensing unit is disposed on the second substrate, and a portion of the second light-emitting units is embedded in the at least one light condensing unit; and/or,
at least one light condensing unit is disposed on a surface of the first substrate adjacent to the second display substrate.

5. The display module of claim 3, wherein the light condensing unit comprises a condenser lens.

6. The display module of claim 3, wherein the light scattering unit is disposed on the first substrate, and is disposed adjacent to at least one of the first light-emitting units.

7. The display module of claim 3, wherein the light scattering unit comprises a light-transmitting base material and scattering particles dispersed in the light-transmitting base material.

8. The display module of claim 3, wherein the light scattering unit comprises a scattering lens.

9. The display module of claim 3, wherein the shape of the light scattering unit is the same as the shape of the first light-emitting units, and the dimension of the light scattering unit is the same as the dimension of the first light-emitting units.

10. The display module of claim 2, wherein the dimming module comprises a light condensing unit and a color conversion unit; and
wherein at least a portion of the light condensing unit is disposed between the second light-emitting units and the first substrate, and an orthographic projection of the light condensing unit on the second substrate overlaps with the orthogonal projections of the second light-emitting units on the second substrate; and
the color conversion unit is disposed on a side of the light condensing unit away from the second light-emitting units, and an orthographic projection of the color conversion unit on the second substrate overlaps with the orthographic projection of the light condensing unit on the second substrate.

11. The display module of claim 10, wherein the color conversion unit is disposed on the first substrate, and is disposed adjacent to at least one of the first light-emitting units.

12. The display module of claim 10, wherein the color conversion unit comprises at least one of a quantum dot and a phosphor.

13. The display module of claim 1, further comprising:
a light-shielding layer disposed on the first substrate and provided with first openings and second openings that are disposed at intervals;
wherein the first light-emitting units are disposed in the first openings, and orthographic projections of the second light-emitting units on the second substrate overlap with orthographic projections of the second openings on the second substrate, respectively.

14. The display module of claim 1, wherein the first display substrate further comprises first driving circuits, and the first driving circuits are connected to the first light-emitting units, respectively; and/or,
wherein the second display substrate further comprises second driving circuits, and the second driving circuits are connected to the second light-emitting units, respectively.

15. The display module of claim 1, further comprising:
an adhesive member disposed between the first display substrate and the second display substrate, and adhering the first display substrate and the second display substrate.

16. The display module of claim 1, further comprising:
an optical modulation layer disposed on a light-emitting side of the first display substrate.

17. The display module of claim 16, wherein the optical modulation layer comprises a slit grating film or lenticular lenses.

18. The display module of claim 16, further comprising:
an encapsulation layer disposed between the optical modulation layer and the first display substrate, wherein the optical modulation layer is disposed on the encapsulation layer.

19. The display module of claim 1, wherein orthographic projections of the plurality of first light-emitting units on the second substrate are adjacent to and spaced apart from orthographic projections of the plurality of second light-emitting units on the second substrate, respectively.
